(19) United States
(12) Patent Application Publication
(10) Pub. No.: US 2026/0271577 A1
(43) Pub. Date: Sep. 10, 2026

(54) DISPLAY PANEL, DISPLAY DEVICE, AND PREPARATION METHOD FOR DISPLAY PANEL

(71) Applicant: Yungu (Gu’an) Technology Co., Ltd., Langfang (CN)

(72) Inventors: Huanhuan ZHANG, Langfang (CN); Rongzhen CUI, Langfang (CN); Teng PAN, Langfang (CN)

(73) Assignee: Yungu (Gu’an) Technology Co., Ltd., Langfang (CN)

(21) Appl. No.: 19/663,196

(22) Filed: Apr. 29, 2026

(30) Foreign Application Priority Data
May 21, 2025 (CN) 202510655787.3

(51) Int. Cl. H10K 59/38; H10K 59/12; H10K 59/122; H10K 59/80

(52) U.S. Cl. CPC H10K 59/38; H10K 59/1201; H10K 59/122; H10K 59/8723; H10K 59/873

(57) ABSTRACT

The present application provides a display panel, a display device, and a method for preparing a display panel. The display panel includes a substrate, a light-emitting functional layer, a bank structure layer, a color conversion layer, and a transparent functional layer. The light-emitting functional layer includes a plurality of light-emitting units. The bank structure layer encloses to form a plurality of first openings respectively corresponding to the plurality of light-emitting units. The plurality of first openings includes at least one first-type opening, at least one second-type opening, and at least one third-type opening. The color conversion layer includes a plurality of color conversion units. The plurality of color conversion units includes at least one first color conversion unit and at least one second color conversion unit having different colors. The first color conversion unit is filled in the first-type opening, and the second color conversion unit is filled in the second-type opening.

### CROSS-REFERENCE TO RELATED APPLICATIONS

The present application claims priority to the Chinese Patent Application No. 202510655787.3, filed on May 21, 2025, and the entire contents of the aforementioned application are hereby incorporated by reference in its entirety.

### FIELD

The present application relates to the field of display technology, and in particular, to a display panel, a display device, and a preparation method for a display panel.

### BACKGROUND

Flat display panels such as Organic Light Emitting Diode (OLED) panels and display panels utilizing Light Emitting Diode (LED) devices are widely used in various consumer electronic products such as mobile phones, televisions, personal digital assistants, digital cameras, notebook computers, and desktop computers due to their advantages of high image quality, low power consumption, thin profile, and wide application range, and have become mainstream in display devices.

### SUMMARY

Embodiments of the present application provide a display panel, a display device, and a preparation method for a display panel, which can improve preparation efficiency.

An embodiment of the present application provides a display panel. The display panel includes a substrate, a light-emitting functional layer, a bank structure layer, a color conversion layer, and a transparent functional layer. The light-emitting functional layer is disposed on one side of the substrate and includes a plurality of light-emitting units. The bank structure layer is disposed on a side of the light-emitting functional layer away from the substrate, and the bank structure layer encloses to form a plurality of first openings respectively corresponding to the plurality of light-emitting units. The plurality of first openings include a first type of opening, a second type of opening, and a third type of opening.

The color conversion layer is disposed on the side of the light-emitting functional layer away from the substrate. The color conversion layer includes a plurality of color conversion units, the plurality of color conversion units including a first color conversion unit and a second color conversion unit having different colors. The first color conversion unit fills the first type of opening, and the second color conversion unit fills the second type of opening. The transparent functional layer is disposed on a side of the color conversion layer away from the substrate. The transparent functional layer includes a filling portion and a covering portion located on a side of the filling portion away from the substrate. The filling portion fills the third type of opening. The covering portion covers the filling portion and covers at least a part of the first color conversion unit and the second color conversion unit, and is integrally connected with the filling portion.

An embodiment of the present application provides a display panel, including:
a substrate;
a light-emitting functional layer disposed on one side of the substrate, the light-emitting functional layer including a plurality of light-emitting units;
a bank structure layer disposed on a side of the light-emitting functional layer away from the substrate, the bank structure layer enclosing to form a plurality of first openings respectively corresponding to the plurality of light-emitting units;
a color conversion layer disposed on the side of the light-emitting functional layer away from the substrate, the color conversion layer including a plurality of color conversion units, the plurality of color conversion units including a first color conversion unit and a second color conversion unit of different colors, the first color conversion unit and the second color conversion unit being filled in different first openings;
an inorganic layer disposed on a side of the color conversion layer away from the substrate;
a first filter layer disposed on a side of the inorganic layer away from the substrate, the first filter layer including a first filter portion;
and the first filter portion is a yellow filter portion which allows yellow light to pass through while absorbing light of other colors, and orthographic projections of both the first color conversion unit and the second color conversion unit on the substrate overlap with an orthographic projection of the first filter portion on the substrate.

An embodiment of the present application provides a method for fabricating a display panel, including:
forming a light-emitting functional layer on one side of a substrate, the light-emitting functional layer including a plurality of light-emitting units;
forming a bank structure layer on a side of the light-emitting functional layer away from the substrate, the bank structure layer enclosing to form a plurality of first openings respectively corresponding to the plurality of light-emitting units, the plurality of first openings including a first type opening, a second type opening, and a third type opening;
forming a color conversion layer on the side of the light-emitting functional layer away from the substrate, the color conversion layer including a plurality of color conversion units, the plurality of color conversion units including a first color conversion unit and a second color conversion unit of different colors, the first color conversion unit being filled in the first type opening, the second color conversion unit being filled in the second type opening;
forming a transparent functional layer on a side of the color conversion layer away from the substrate, the transparent functional layer including a filling portion and a covering portion located on a side of the filling portion away from the substrate, the filling portion being filled in the third type opening, the covering portion covering the filling portion and covering at least a part of the first color conversion unit and the second color conversion unit, and being integrally connected with the filling portion.

An embodiment of the present application provides a display device, the display device including the display panel according to any one of the foregoing embodiments and the display panel formed by the fabrication method according to any one of the foregoing embodiments.

The embodiments of the present application provide a display panel, a display device, and a method for fabricating a display panel. The transparent portion filled in the third type opening and the covering portion used to cover the transparent portion and the color conversion units are both located within the transparent functional layer and are integrally connected. In other words, they include the same material and are formed together in the same process step. Compared to conventional processes where a transparent film layer and a transparent structure are formed separately, and the transparent structure requires a mask, this design can save process steps. Furthermore, since the formed transparent functional layer itself is a full-surface structure, this design can also save two mask processes, simplifying fabrication difficulty, reducing fabrication cost, and improving fabrication efficiency.

### BRIEF DESCRIPTION OF THE DRAWINGS

FIG. 1 is a schematic cross-sectional structural diagram of a display panel provided by an embodiment of the present application;

FIG. 2 is a schematic cross-sectional structural diagram of another display panel provided by an embodiment of the present application;

FIG. 3 is a schematic cross-sectional structural diagram of yet another display panel provided by an embodiment of the present application;

FIG. 4 is a schematic cross-sectional structural diagram of yet another display panel provided by an embodiment of the present application;

FIG. 5 is a schematic cross-sectional structural diagram of yet another display panel provided by an embodiment of the present application;

FIG. 6 is a schematic cross-sectional structural diagram of yet another display panel provided by an embodiment of the present application;

FIG. 7 is a schematic cross-sectional structural diagram of yet another display panel provided by an embodiment of the present application;

FIG. 8 is a schematic cross-sectional structural diagram of yet another display panel provided by an embodiment of the present application;

FIG. 9 is a schematic cross-sectional structural diagram of yet another display panel provided by an embodiment of the present application;

FIG. 10 is a schematic cross-sectional structural diagram of yet another display panel provided by an embodiment of the present application;

FIG. 11 is a schematic cross-sectional structural diagram of yet another display panel provided by an embodiment of the present application;

FIG. 12 is a schematic cross-sectional structural diagram of a light-emitting unit in a display panel provided by an embodiment of the present application;

FIG. 13 is a flowchart of a method for fabricating a display panel provided by an embodiment of the present application;

FIG. 14a to FIG. 14d are schematic diagrams showing structural processes of a method for fabricating a display panel provided by an embodiment of the present application;

FIG. 15 is a flowchart of another method for fabricating a display panel provided by an embodiment of the present application;

FIG. 16 is a schematic diagram showing structural processes of another method for fabricating a display panel provided by an embodiment of the present application;

FIG. 17 is a schematic structural diagram of a display device provided by an embodiment of the present application.

### DETAILED DESCRIPTION OF THE EMBODIMENTS

The features and exemplary embodiments of various aspects of the present application will be described in detail below. In order to make the objectives, embodiments, and advantages of the present application clearer, the present application is further described in detail below with reference to the accompanying drawings and specific embodiments. It should be understood that the specific embodiments described herein are only intended to explain the present application, rather than to limit the present application. The present application can be implemented without some of these specific details. The following description of the embodiments is merely provided to give a better understanding of the present application by illustrating examples of the present application.

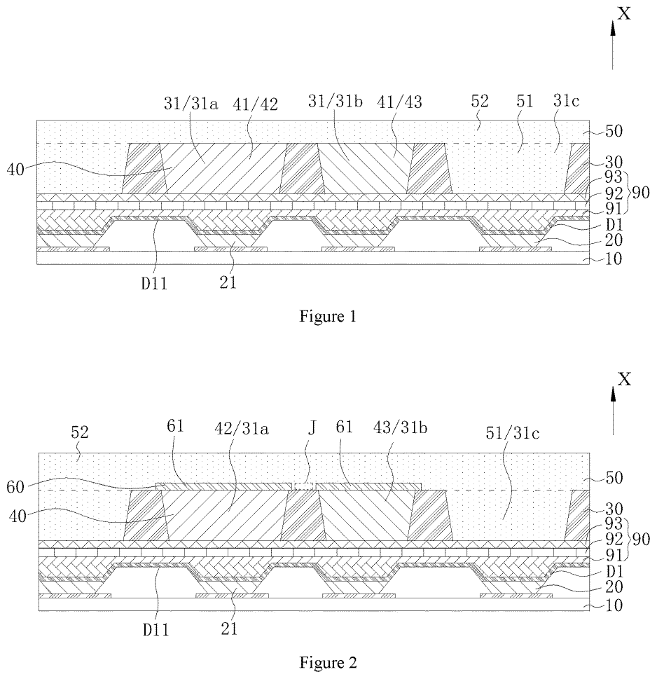

In a first aspect, referring to FIG. 1, an embodiment of the present application provides a display panel. The display panel includes a substrate 10, a light-emitting functional layer 20, a bank structure layer 30, a color conversion layer, and a transparent functional layer 50. The light-emitting functional layer 20 is disposed on one side of the substrate 10, and the light-emitting functional layer 20 includes a plurality of light-emitting units 21. The bank structure layer 30 is disposed on a side of the light-emitting functional layer 20 away from the substrate 10. The bank structure layer 30 encloses to form a plurality of first openings 31 respectively corresponding to the plurality of light-emitting units 21. The plurality of first openings 31 include a first type opening 31a, a second type opening 31b, and a third type opening 31c.

The color conversion layer 40 is disposed on a side of the light-emitting functional layer 20 away from the substrate 10. The color conversion layer 40 includes a plurality of color conversion units 41. The plurality of color conversion units 41 include a first color conversion unit 42 and a second color conversion unit 43 having different colors. The first color conversion unit 42 fills the first type opening 31a, and the second color conversion unit 43 fills the second type opening 31b. The transparent functional layer 50 is disposed on a side of the color conversion layer 40 away from the substrate 10. The transparent functional layer 50 includes a filling portion 51 and a covering portion 52 located on a side of the filling portion 51 away from the substrate 10. The filling portion 51 fills the third type opening 31c. The covering portion 52 covers the filling portion 51 and covers at least a portion of the first color conversion unit 42 and the second color conversion unit 43, and is integrally connected with the filling portion 51.

The substrate 10 primarily serves a supporting and carrying function, with other film layers sequentially stacked on the substrate 10. The term “stacked” mentioned here refers to the arrangement of other film layers along the thickness direction X of the substrate 10. The substrate 10 may include multiple film layer structures, and the specific composition of the internal film layer structures of the substrate 10 is not limited in the embodiments of this application. Moreover, the thickness direction X of the other film layers located on one side of the substrate 10 is typically consistent with the thickness direction X of the substrate 10 itself. Therefore, for convenience of description, the thickness direction X of the substrate 10 or the thickness direction X of the other film layers mentioned subsequently in the embodiments of this application is illustrated using the same direction. The light-emitting functional layer 20 is located on one side of the substrate 10. In a direction parallel to the plane of the substrate 10, the light-emitting functional layer 20 includes multiple light-emitting units 21, which are the main devices for achieving light-emitting display. Each light-emitting unit 21 may include a stacked arrangement of a hole injection layer (HIL), a hole transport layer (HTL), a light-emitting layer 211, an electron injection layer (EIL), and an electron transport layer (ETL). In one embodiment, the display panel may further include a pixel definition layer P. The pixel definition layer P includes pixel defining portions P1 and pixel openings P2 formed by the enclosure of the pixel defining portions P1. Multiple light-emitting units 21 are respectively disposed within multiple pixel openings P2. Among them, the light-emitting units 21 located in different pixel openings P2 may be spaced apart from each other, or at least some adjacent light-emitting units 21 in pixel openings P2 may be integrally connected. The embodiments of this application impose no restrictions on this. Furthermore, the display panel also includes a first electrode layer D1 and a second electrode layer located on both sides of the light-emitting functional layer 20 in the thickness direction X. The first electrode layer D1 is located on the side of the light-emitting functional layer 20 away from the substrate 10, and the second electrode layer is located on the side of the light-emitting functional layer 20 facing the substrate 10. The first electrode layer D1 includes a first electrode D11, and the second electrode layer includes multiple second electrodes. The multiple second electrodes correspond to the light-emitting units 21, and the first electrode D11 and the second electrodes together drive and control whether the light-emitting units 21 emit light. For example, the first electrode D11 is a cathode, and the second electrodes are anodes. The bank structure layer 30 is located on the side of the light-emitting functional layer 20 away from the substrate 10 and encloses to form multiple first openings 31. The orthographic projection of the first openings 31 on the substrate 10 overlaps with the orthographic projection of the light-emitting units 21 on the substrate 10. Different first openings 31 correspond to different light-emitting units 21, and the first openings 31 are used to limit and accommodate part of the film layer structure to meet the preparation requirements of the display panel. The specific material composition of the bank structure layer 30 is not limited in the embodiments of this application. In one embodiment, the bank structure layer 30 may include a light-shielding material, and that the bank structure layer 30 can also be used to block or absorb part of the oblique light, thereby reducing the risk of display crosstalk. The color conversion layer 40 is located on the side of the light-emitting functional layer 20 away from the substrate 10. The color conversion layer 40 includes multiple color conversion units 41. The color conversion units 41 can change the color of light after being excited by light of a specific color and allow the light with the changed color to exit the display panel. Optionally, the color conversion units 41 may be quantum dot structures. Furthermore, in the embodiments of this application, the orthographic projection of the color conversion units 41 on the substrate 10 is at least partially overlapped with the orthographic projection of the light-emitting units 21 on the substrate 10, meaning that the color conversion units 41 can correspond to the light-emitting units 21. In this way, light of a specific color emitted by the light-emitting units 21 can irradiate the color conversion units 41 and excite them, causing the color conversion units 41 to emit light of a different color from that of the light-emitting units 21. The transparent functional layer 50 is disposed on the side of the color conversion layer 40 away from the substrate 10, meaning that the transparent functional layer 50 is formed after the color conversion layer 40. The transparent functional layer 50 includes a covering portion 52 and a filling portion 51. Both the covering portion 52 and the filling portion 51 include transparent materials. Light reaching the transparent functional layer 50 can exit the display panel through at least one of the covering portion 52 and the filling portion 51. The covering portion 52 and the color conversion layer 40 are stacked in the thickness direction X of the display panel, and the orthographic projection of the covering portion 52 on the substrate 10 may overlap with the orthographic projections of multiple color conversion units 41 on the substrate 10. The filling portion 51 and the color conversion units 41 are arranged spaced apart in a direction parallel to the plane of the substrate 10. Among them, part of the structure of the bank structure layer 30 is provided between the filling portion 51 and the color conversion units 41, while the covering portion 52 and the color conversion units 41 may be in direct contact, or there may be other film layer structures between them. The multiple first openings 31 in the bank structure layer 30 include first-type openings 31a, second-type openings 31b, and third-type openings 31c. There are multiple first-type openings 31a, second-type openings 31b, and third-type openings 31c, and they are respectively filled with different structures. Specifically, the multiple color conversion units 41 include first color conversion units 42 and second color conversion units 43 of different colors. The first color conversion units 42, second color conversion units 43, and filling portion 51 are respectively filled in the first-type openings 31a, second-type openings 31b, and third-type openings 31c. On this basis, the color of light emitted by the display panel in the area where the first-type openings 31a are located is the color corresponding to the first color conversion units 42, the color of light emitted in the area where the second-type openings 31b are located is the color corresponding to the second color conversion units 43, and the color of light emitted in the area where the third-type openings 31c are located is the light-emitting color corresponding to the light-emitting units 21 themselves.

Regarding the specific color types of the first color conversion unit 42 and the second color conversion unit 43, the embodiments of the present application impose no limitations, as long as the colors of the first color conversion unit 42 and the second color conversion unit 43 are different and both are different from the light-emitting color of the light-emitting unit 21. The covering portion 52 may completely cover the first color conversion unit 42 and the second color conversion unit 43, or at least a partial structure of one of the first color conversion unit 42 and the second color conversion unit 43 may have its orthographic projection on the substrate located outside the orthographic projection of the covering portion 52 on the substrate. The embodiments of the present application impose no limitations on this.

Taking a quantum dot display device as an example, in related technologies, a quantum dot structure is provided on the light-emitting side of some light-emitting structures, while a transparent structure is provided on the light-emitting side of other light-emitting structures. The quantum dot structure and the transparent structure are arranged side by side in the horizontal direction, and a transparent film layer is further coated on the light-emitting side of the quantum dot structure and the transparent structure to provide protection and other effects. This design often involves multiple process steps during preparation, making the process relatively complex and affecting preparation efficiency and cost.

However, in the embodiments of the present application, the transparent portion filled in the third type of opening 31c and the covering portion 52 used to cover the transparent portion and the color conversion unit 41 are both located within the transparent functional layer 50 and are integrally connected. In other words, they include the same material and are formed together in the same process step. Compared to conventional processes where the transparent film layer and the transparent structure are formed separately, and the transparent structure requires a mask, this design can save process steps. Moreover, since the formed transparent functional layer 50 itself is a full-surface structure, this design can also save two mask processes, simplifying preparation difficulty, reducing preparation cost, and improving preparation efficiency.

In some embodiments, referring to FIG. 2, the display panel further includes a first filter layer 60 disposed between the color conversion layer 40 and the transparent functional layer 50. The orthographic projection of the color conversion unit 41 on the substrate 10 overlaps with the orthographic projection of the first filter layer 60 on the substrate 10. The covering portion 52 covers the first filter layer 60.

The first filter layer 60 is disposed on the side of the color conversion layer 40 away from the substrate 10. The first filter layer 60 can filter light emitted from the color conversion unit 41 to improve the accuracy of the final light color emitted from the display panel. The first filter layer 60 can have various forms. For example, the first filter layer 60 may include multiple filter portions of different colors, or it may only include a single-color filter portion.

In the embodiments of the present application, the first filter layer 60 is not only located on the side of the color conversion layer 40 away from the substrate 10 but also on the side of the transparent functional layer 50 facing the substrate 10. On this basis, the covering portion 52 can be stacked with the first filter layer 60 in the thickness direction X of the display panel, and the covering portion 52 can cover the first filter layer 60. Thus, in addition to protecting the color conversion structure, the covering portion 52 can also protect the first filter layer 60, thereby improving the structural reliability and service life of the display panel.

In some embodiments, the covering portion 52 covers the first color conversion unit 42, the second color conversion unit 43, and the filling portion 51. By designing the covering portion 52 to completely cover the first color conversion unit 42 and the second color conversion unit 43, the protective effect of the covering portion 52 on the first color conversion unit 42 and the second color conversion unit 43 can be further enhanced, improving the structural reliability and service life of the display panel.

In some embodiments, referring to FIG. 2, the first filter layer 60 includes a first filter portion 61. The first color conversion unit 42 is a red conversion unit 41, the second color conversion unit 43 is a green conversion unit 41, and the first filter portion 61 is a yellow filter portion. The orthographic projections of both the first color conversion unit 42 and the second color conversion unit on the substrate 10 overlap with the orthographic projection of the first filter portion 61 on the substrate 10.

The first color conversion unit 42 is a red conversion unit 41, meaning that when excited by light of a specific color, it emits red light. The second color conversion unit 43 is a green conversion unit 41, meaning that when excited by light of a specific color, it emits green light.

The first filter portion 61 is a yellow filter portion. The yellow filter portion allows yellow light to pass through while absorbing light of other colors. In the optical color model, yellow light is formed by combining red light and green light. Therefore, the yellow filter portion allows both red light and green light to be emitted. In other words, the first filter portion 61 can correspond to both the first color conversion unit 42 and the second color conversion unit 43.

In the embodiments of the present application, for the case where the first color conversion unit 42 and the second color conversion unit 43 are a red conversion unit 41 and a green conversion unit 41, respectively, setting the first filter portion 61 as a yellow filter portion allows it to correspond to both the first color conversion unit 42 and the second color conversion unit 43. Thus, the first filter portions 61 corresponding to color conversion units 41 of different colors can include the same material and be formed together in the same process step, which helps simplify the process, improve preparation efficiency, and reduce preparation cost.

It should be noted that the embodiments of the present application describe the case where the first color conversion unit 42 and the second color conversion unit 43 are a red conversion unit 41 and a green conversion unit 41, respectively, and the first filter portion 61 is a yellow filter portion. In other embodiments, the first color conversion unit 42 and the second color conversion unit 43 may be conversion units of other colors, and the first filter portion 61 may also be a filter portion of another color, as long as the first filter portion 61 allows both the light corresponding to the first color conversion unit 42 and the light corresponding to the second color conversion unit 43 to be emitted.

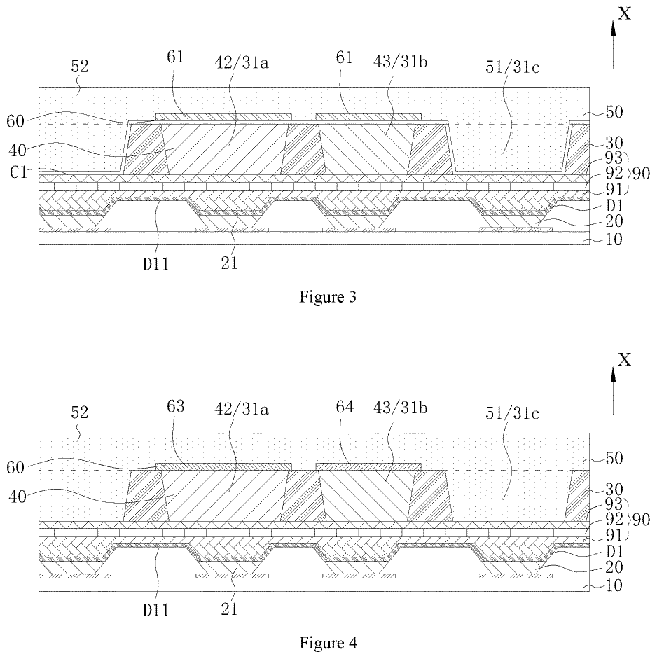

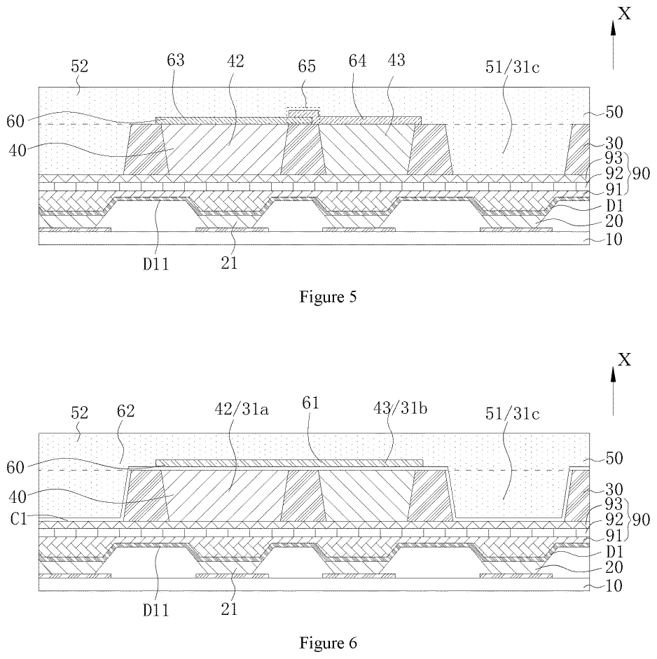

In addition, although both the first color conversion unit 42 and the second color conversion unit 43 are correspondingly and overlappingly arranged with the first filter portion 61, it is not limited that the first color conversion unit 42 and the second color conversion unit 43 are correspondingly and overlappingly arranged with a single first filter portion 61. In other words, the first color conversion unit 42 and the second color conversion unit 43 can be respectively correspondingly arranged with different first filter portions 61 that are spaced apart, or a single first filter portion 61 can also be correspondingly and overlappingly arranged with both the first color conversion unit 42 and the second color conversion unit 43 simultaneously. In some embodiments, as shown in FIG. 2, the first filter portion 61 corresponding to the first color conversion unit 42 and the first filter portion 61 corresponding to the second color conversion unit 43 are spaced apart, meaning the first color conversion unit 42 and the second color conversion unit 43 are respectively correspondingly arranged with different first filter portions 61. Further, in one embodiment, adjacent first filter portions 61 are spaced apart to form a gap space J, and a portion of the structure of the covering portion 52 is located within the gap space J. In the embodiments of the present application, in addition to covering the surface of the first filter portion 61 facing away from the substrate 10, the covering portion 52 can also be attached to the peripheral side surface of the first filter portion 61. This can further improve the covering effect of the covering portion 52 on the first filter portion 61, enhance the protective effect of the transparent functional layer 50 on the first filter layer 60, and improve the reliability and service life of the display panel. In some embodiments, referring to FIG. 3, the display panel further includes an inorganic layer C1 disposed between the color conversion layer 40 and the first filter layer 60, with both the filling portion 51 and the first filter portion 61 located on a side of the inorganic layer C1 facing away from the substrate 10. The inorganic layer C1 can separate the color conversion layer 40 from the first filter layer 60, thereby reducing the impact of the manufacturing process of the first filter layer 60 on the structure of the color conversion layer 40. The inorganic layer C1 has a full-surface structure, and the orthographic projection of the inorganic layer C1 on the substrate 10 overlaps with the orthographic projections of the first color conversion unit 42, the second color conversion unit 43, and the filling portion 51 on the substrate 10. In related technologies, transparent structures arranged side by side with quantum dot structures in the horizontal direction are often located below an inorganic film layer, while a transparent film layer covering the quantum dot structures and the transparent structures is located below the inorganic film layer. However, in the embodiments of the present application, both the filling portion 51 and the first filter portion 61 are located on the side of the inorganic layer C1 facing away from the substrate 10. This allows the filling portion 51 and the covering portion 52 to be located on the same side of the inorganic layer C1, enabling the filling portion 51 and the covering portion 52 to be integrally connected and formed in the same process step, thereby simplifying the manufacturing process of the display panel. In some embodiments, referring to FIG. 4, the first filter layer 60 includes a second filter portion 63 and a third filter portion 64 of different colors. The orthographic projection of the second filter portion 63 on the substrate 10 overlaps with the orthographic projection of the first color conversion unit 42 on the substrate 10, and the orthographic projection of the third filter portion 64 on the substrate 10 overlaps with the orthographic projection of the second color conversion unit 43 on the substrate 10. In addition to the scheme where both the first color conversion unit 42 and the second color conversion unit 43 are overlappingly arranged with the first filter portion 61, the first filter layer 60 can also be configured to include the second filter portion 63 and the third filter portion 64, which are of different colors and respectively correspond to the first color conversion unit 42 and the second color conversion unit 43. For example, if the first color conversion unit 42 and the second color conversion unit 43 are a red conversion unit and a green conversion unit, respectively, then the first filter portion 61 can be a red filter portion correspondingly and overlappingly arranged with the red conversion unit, and the second filter portion 63 can be a green filter portion correspondingly and overlappingly arranged with the green conversion unit. Furthermore, regarding the positional relationship between the second filter portion 63 and the third filter portion 64, the embodiments of the present application impose no limitations. In some embodiments, as shown in FIG. 4, adjacent second filter portions and third filter portions are spaced apart. In one embodiment, referring to FIG. 5, adjacent second filter portion 63 and third filter portion 64 overlap to form an overlapping portion 65. The orthographic projection of the overlapping portion 65 on the substrate 10 is located between the orthographic projections of adjacent first color conversion unit 42 and second color conversion unit 43 on the substrate 10. With this design, the overlapping portion 65 can include filter materials of different colors. Through the combined action of these different colored filter materials, absorption of partially obliquely emitted light can be achieved, reducing the risk of light crosstalk. Simultaneously, the overlapping portion 65 can reduce light reflection, thereby improving the display effect and precision of the display panel. In some embodiments, referring to FIG. 6, the first filter portion 61 corresponding to the first color conversion unit 42 and the first filter portion 61 corresponding to the second color conversion unit 43 are integrally connected. In the embodiments of the present application, the orthographic projection of a single first filter portion 61 on the substrate 10 overlaps with both the orthographic projection of the first color conversion unit 42 on the substrate 10 and the orthographic projection of the second color conversion unit 43 on the substrate 10. This helps to increase the orthographic projection area of a single first filter portion 61 on the substrate 10, thereby reducing the manufacturing difficulty of the first filter portion 61. It also helps to lower the alignment accuracy requirement of the first filter portion 61 relative to the first color conversion unit 42 and the second color conversion unit 43, reducing the complexity of the display panel manufacturing process and improving the manufacturing yield. It should be noted that, depending on actual needs, the first filter portion 61 corresponding to a single first color conversion unit 42 and the first filter portion 61 corresponding to a single second color conversion unit 43 can be chosen to be integrally connected, or the first filter portions 61 corresponding to multiple first color conversion units 42 and the first filter portions 61 corresponding to multiple second color conversion units 43 can be chosen to be integrally connected. The embodiments of the present application impose no limitations in this regard. In some embodiments, the orthographic projections of multiple first color conversion units 42 and multiple second color conversion units 43 on the substrate 10 all overlap with the orthographic projection of the same first filter portion 61 on the substrate 10. This can further increase the orthographic projection area of a single first filter portion 61 on the substrate 10, reduce the alignment accuracy requirement of the first filter portion 61 relative to the first color conversion units 42 and the second color conversion units 43, and improve the manufacturing yield.

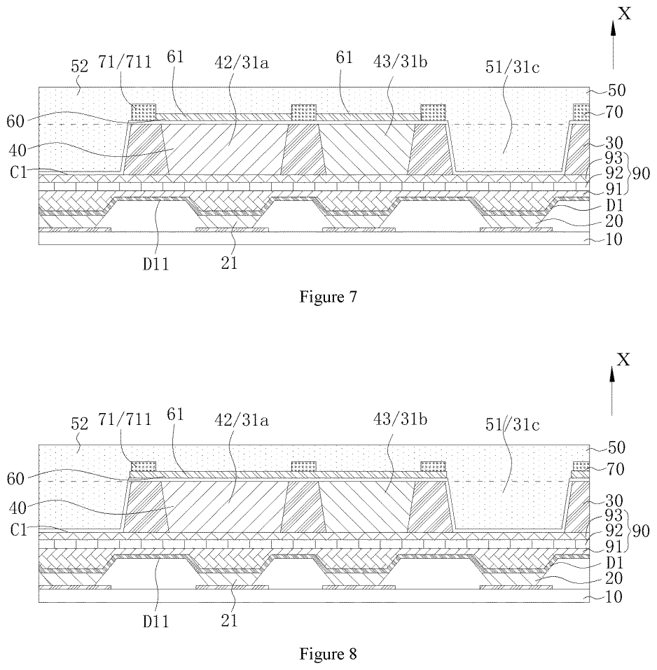

In some embodiments, the orthographic projection of a single first filter portion 61 on the substrate 10 covers the orthographic projections of all first color conversion units 42 and all second color conversion units 43 on the substrate 10, and the first filter portion 61 encloses to form a plurality of second openings 62. The orthographic projections of the plurality of second openings 62 and the plurality of third-type openings 31c on the substrate 10 are correspondingly overlapped. Among them, a portion of the structure in the covering portion 52 is located within the second opening 62. The first filter portion 61 is an entire-surface structure with openings and is correspondingly arranged with all first color conversion units 42 and all second color conversion units 43. The first filter portion 61 includes second openings 62 corresponding to the third-type openings 31c. During the manufacturing process of the display panel, since the transparent functional layer 50 is formed after the first filter layer 60, the transparent material used to form the transparent functional layer 50 can pass through the second openings 62 and enter the third-type openings 31c to form the filling portion 51 filled within the third-type openings 31c. The transparent material falling on the surface of the first filter portion 61 away from the substrate 10 and the transparent material on the surface of the filling portion 51 away from the substrate 10 together constitute the covering portion 52, thereby achieving the co-fabrication of the covering portion 52 and the filling portion 51 in the same process step. In the embodiments of the present application, by configuring the first filter portion 61 as an entire-surface structure, the manufacturing difficulty of the first filter portion 61 is further reduced, while the alignment accuracy requirement of the first filter portion 61 relative to the first color conversion units 42 and the second color conversion units 43 is further lowered, thereby improving manufacturing yield. On this basis, the embodiments of the present application further provide second openings 62 in the first filter portion 61 corresponding to the third-type openings 31c. The arrangement of the second openings 62 allows part of the transparent material to fall into the third-type openings 31c, thereby achieving the co-fabrication of the covering portion 52 and the filling portion 51 in the same process step and improving the manufacturing efficiency of the display panel. In some embodiments, the first filter portion 61 includes a first colloid portion and a first quantum dot structure located within the first colloid portion. The first filter portion 61 includes both quantum dot material and colloid material, i.e., the first filter portion 61 is a quantum dot photoresist. Quantum dot photoresist is a novel photolithographic material that mixes quantum dot luminescent material with photoresist and uses appropriate semiconductor processes and photolithography techniques to pattern it on the substrate 10. For example, the patterning method of the quantum dot photoresist can be consistent with that of conventional photoresist, i.e., the first filter portion 61 can be formed through development and exposure processes. In the embodiments of the present application, the structural composition of the first filter portion 61 is adjusted. The first filter portion 61 is not a conventional filter structure but is a quantum dot photoresist including a first colloid portion and a first quantum dot structure within the first colloid portion. This design, on one hand, meets the filtering requirements, and on the other hand, allows the first filter portion 61 to be patterned through development and exposure processes. Compared to conventional etching processes, this design helps simplify the patterning process of the first filter portion 61. Regarding the material composition of the first colloid portion, the embodiments of the present application impose no limitations. In one embodiment, the material of the first colloid portion includes photosensitive material. Photosensitive materials refer to a class of materials that undergo chemical reactions or physical changes under light irradiation of specific wavelengths. The inclusion of photosensitive material enables the first filter portion 61 to be patterned through development and exposure processes, thereby simplifying the patterning process. In some embodiments, the material of the first filter portion 61 includes at least one of acrylic, epoxy resin, and mica powder. Both acrylic and epoxy resin are photosensitive materials, while mica powder is an inorganic mineral filler used to enhance the mechanical properties of the material and improve certain physical characteristics. Among these, acrylic, epoxy resin, and mica powder are low-temperature processing materials. By incorporating at least one of the above materials into the first filter portion 61, it helps reduce damage to the first quantum dot structure during the manufacturing process. Regarding the specific type of the first quantum dot structure, the embodiments of the present application impose no limitations. For the case where the first filter portion 61 is a yellow filter portion, in one embodiment, the first quantum dot structure is a yellow quantum dot structure. The arrangement of the yellow quantum dot structure allows red and green light to pass through while absorbing light of other colors, thereby achieving a filtering effect on light. In some embodiments, the display panel further includes a protective layer C2 disposed between the first filter layer 60 and the transparent functional layer 50, with the protective layer C2 covering the first filter portion 61. In the embodiments of the present application, the protective layer C2 is formed after the first filter layer 60 and is located on the side of the first filter layer 60 away from the substrate 10. The presence of the protective layer C2 can provide a protective effect for the first filter portion 61, thereby improving the performance stability of the first filter portion 61. In some embodiments, at least part of the color conversion units 41 includes a second colloid portion and a second quantum dot structure located within the second colloid portion. Similar to the first filter portion 61, the color conversion units 41 can also be configured as quantum dot photoresist. Unlike the first filter portion 61, the first quantum dot structure can be a yellow quantum dot structure, while the second quantum dot structure can be a red quantum dot structure or a green quantum dot structure. In the embodiments of the present application, by configuring the color conversion units 41 to include a second colloid portion and a second quantum dot structure, the color conversion units 41 can be patterned through development and exposure processes, thereby simplifying the patterning process of the color conversion units 41. In some embodiments, please refer to FIG. 7, the display panel further includes a second filter layer 70 disposed on the side of the first filter layer 60 away from the substrate 10. The second filter layer 70 includes a fourth filter portion 71, and the fourth filter portion 71 has the same color as the light-emitting units 21. Among them, the fourth filter portion 71 includes a first portion 711 located on the side of the covering portion 52 facing the substrate 10, and the orthographic projection of the first portion 711 on the substrate 10 is located between the orthographic projections of adjacent light-emitting units 21 on the substrate 10.

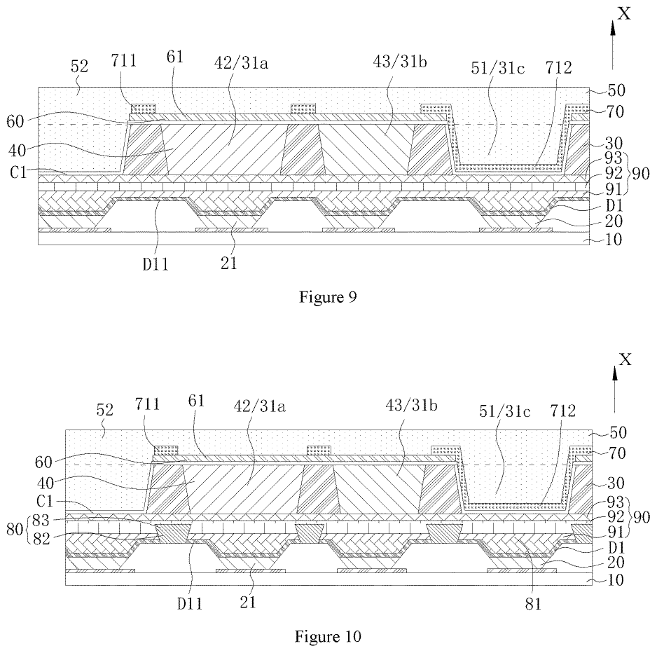

Similar to the first filter layer 60, the second filter layer 70 is also a film layer structure used for filtering light, and the second filter layer 70 is formed after the first filter layer 60. The second filter layer 70 includes a fourth filter portion 71, which has the same color as the light-emitting unit 21, meaning the fourth filter portion 71 has a different color from the first filter portion 61. In one embodiment, the light-emitting unit 21 is a blue light-emitting unit 21, and the fourth filter portion 71 is a blue filter portion. The first part 711 is a structure within the fourth filter portion 71 corresponding to the area between adjacent light-emitting units 21, and the first part 711 is located on the light-emitting side of the color conversion unit 41 and the filling portion 51. The projection positional relationship of the first part 711 relative to the color conversion unit 41 and the filling portion 51 is not limited in the embodiments of this application. In one embodiment, at least a portion of the first part 711 has an orthographic projection on the substrate 10 located between the orthographic projections of two adjacent color conversion units 41 on the substrate 10. In this way, oblique light emitted from the color conversion unit 41 propagates to the first part 711. Since the first part 711 has a different color from the color conversion unit 41, the oblique light emitted from the color conversion unit 41 is absorbed by the first part 711, thereby reducing the risk of crosstalk between light of different colors. Of course, in some embodiments, at least a portion of the first part 711 has an orthographic projection on the substrate 10 located between the orthographic projections of an adjacent color conversion unit 41 and the filling portion 51 on the substrate 10. In this design, oblique light emitted from the color conversion unit 41 is similarly absorbed by the first part 711, thereby reducing the risk of light crosstalk. The first part 711 is located on the side of the covering portion 52 facing the substrate 10. In addition to providing covering protection for the first filter portion 61, the covering portion 52 can also provide covering protection for the first part 711, thereby further improving the reliability and service life of the display panel. It should be noted that, depending on actual needs, the fourth filter portion 71 may only include the first part 711, or in addition to the first part 711, the fourth filter portion 71 may also include other components, which is not limited in the embodiments of this application. In the embodiments of this application, a second filter layer 70 is added to the display panel. The first part 711 in the second filter layer 70 is correspondingly located between adjacent light-emitting units 21, and oblique light emitted from the color conversion layer 40 is absorbed by the first part 711, thereby reducing the risk of light crosstalk and improving color gamut while enhancing hue. At the same time, this design eliminates the need for a light-shielding layer, thereby simplifying the manufacturing process of the display panel. In some embodiments, the number of first filter portions 61 is multiple, and adjacent first filter portions 61 are spaced apart to form a gap space J, with the first part 711 located within the gap space J. In the embodiments of this application, the first part 711 is located between adjacent first filter portions 61. The thickness dimension of the first part 711 may be greater than, less than, or equal to the thickness dimension of the first filter portion 61. In one embodiment, the thickness dimension of the first part 711 is greater than that of the first filter portion 61, allowing the first part 711 to absorb more oblique light, thereby further improving the display accuracy of the display panel. In other embodiments, referring to FIG. 8, the first filter portions 61 corresponding to color conversion units 41 of different colors are integrally connected, and the first part 711 is in contact with the surface of the first filter portion 61 facing away from the substrate 10. In the embodiments of this application, the display panel has both the first part 711 and a portion of the structure of the first filter portion 61 in the area between adjacent light-emitting units 21. In one embodiment, the first filter portion 61 may be a yellow filter portion, while the first part 711 may be a blue filter portion. In this way, the yellow filter portion and the blue filter portion are stacked together to achieve an effect similar to a black matrix, thereby reducing the crosstalk risk of the display panel and improving the display effect. In some embodiments, referring to FIG. 9, the fourth filter portion 71 further includes a second part 712, which is located within the third-type opening 31c and overlaps with the orthographic projection of the light-emitting unit 21 on the substrate 10. In addition to the first part 711, the fourth filter portion 71 also includes a second part 712. The second part 712 is not located between adjacent light-emitting units 21 but is located within the third-type opening 31c and overlaps with the orthographic projection of the light-emitting unit 21 on the substrate 10. The first part 711 and the second part 712 are made of the same material and are formed in the same process. In one embodiment, the first part 711 and the second part 712 are integrally connected. Based on the foregoing, the fourth filter portion 71 has the same color as the light-emitting unit 21, so light emitted by the light-emitting unit 21 can exit through the fourth filter portion 71. In view of this, the embodiments of this application position the second part 712 of the fourth filter portion 71 within the third-type opening 31c, allowing light emitted by the light-emitting unit 21 to exit the display panel through the third-type opening 31c. At the same time, light of other colors reaching the third-type opening 31c is absorbed by the second part 712, thereby improving the display accuracy and effect of the display panel. In some embodiments, the second part 712 is located on the side of the filling portion 51 facing the substrate 10. In the embodiments of this application, the second filter layer 70 is formed before the transparent functional layer. The second part 712 is located on the side of the filling portion 51 facing the substrate 10, while the covering portion 52 is located on the side of the filling portion 51 facing away from the second part 712. Therefore, during the manufacturing process, the presence of the second part 712 does not affect the integral connection between the covering portion 52 and the filling portion 51. On this basis, the covering portion 52 and the filling portion 51 can be formed in the same process, thereby simplifying the manufacturing process and improving efficiency. In some embodiments, the display panel further includes an inorganic layer C1 disposed between the color conversion layer 40 and the first filter layer 60. Both the first filter portion 61 and the fourth filter portion 71 are located on the side of the inorganic layer C1 facing away from the substrate 10.

In the embodiments of the present application, the first filter portion 61 and the fourth filter portion 71 are interposed between the inorganic layer C1 and the transparent functional layer 50. Through the mutual cooperation of the inorganic layer C1 and the transparent functional layer 50, the protective effect on the first filter portion 61 and the fourth filter portion 71 can be enhanced, thereby improving the reliability and service life of the display panel. Further in one embodiment, both the first filter portion 61 and the fourth filter portion 71 are arranged in contact with the inorganic layer C1.

In some embodiments, referring to FIG. 10, the display panel further includes an isolation structure 80 disposed on one side of the substrate 10. The isolation structure 80 encloses to form a plurality of isolation openings 81, and the plurality of light-emitting units 21 correspond to the plurality of isolation openings 81.

The light-emitting functional layer 20 and the isolation structure 80 are located on the same side of the substrate 10. The plurality of light-emitting units 21 correspond to the plurality of isolation openings 81, meaning that the orthographic projections of the plurality of light-emitting units 21 on the substrate 10 respectively overlap with the orthographic projections of the plurality of isolation openings 81 on the substrate 10. During the manufacturing process of the display panel, by adjusting the size and shape of the isolation structure 80 according to actual usage requirements, the plurality of light-emitting units 21 can be formed together in the same process without the need for a fine metal mask, thereby reducing manufacturing costs. Meanwhile, the presence of the plurality of color conversion units 41 can meet the need for the display panel to display different colors, thus eliminating the need to set up an excessive number of light-emitting units 21 of different colors. This can reduce the risk of prolonged manufacturing time for the display panel due to an excessive variety of light-emitting units 21, helps improve the manufacturing efficiency of the display panel, and offers strong flexibility to meet the manufacturing needs of different display panels.

In some embodiments, the isolation structure 80 includes a first isolation portion 82 and a second isolation portion 83 located on a side of the first isolation portion 82 away from the substrate 10. The orthographic projection of the first isolation portion 82 on the substrate 10 is located within the orthographic projection of the second isolation portion 83 on the substrate 10.

The isolation structure 80 includes at least the first isolation portion 82 and the second isolation portion 83. The orthographic projection of the second isolation portion 83 on the substrate 10 can cover and extend beyond the orthographic projection of the first isolation portion 82 on the substrate 10. Thus, the cross-section of the isolation structure 80 can present an inverted trapezoidal structure as shown in FIG. 9, or it can also present a structure similar to a “T” shape. Further in one embodiment, the isolation structure 80 further includes a third isolation portion located on a side of the first isolation portion 82 facing the substrate 10. The orthographic projection of the first isolation portion 82 on the substrate 10 is located within the orthographic projection of the third isolation portion on the substrate 10, and the cross-section of the isolation structure 80 can present a structure similar to an “I” shape.

In the embodiments of the present application, the arrangement of the first isolation portion 82 and the second isolation portion 83 helps, during the manufacturing process of the light-emitting functional layer 20, to make it difficult for the light-emitting material to extend along the sidewall of the first isolation portion 82 to the sidewall of the second isolation portion 83. Thus, without the need for a fine metal mask, the manufacturing and mutual separation of the light-emitting units 21 in different isolation openings 81 can be achieved, reducing manufacturing costs.

In some embodiments, the display panel further includes a first electrode layer D1 disposed on a side of the light-emitting functional layer 20 away from the substrate 10. The first electrode layer D1 includes a plurality of first electrodes D11 corresponding to the plurality of isolation openings 81.

The first electrodes D11 are used to drive and control the light-emitting units 21 to achieve light-emitting display. The manufacturing method of the first electrode layer D1 can be similar to that of the light-emitting functional layer 20. That is, during the manufacturing process of the first electrode layer D1, the isolation structure 80 can also be utilized to form the plurality of first electrodes D11 located in the plurality of isolation openings 81. This design allows the first electrodes D11 to correspond to the light-emitting units 21, thereby enabling independent or partitioned control of the light-emitting units 21 by the first electrodes D11 according to actual needs.

In some embodiments, the first isolation portion 82 includes a conductive material, and the first electrode D11 is electrically connected to the first isolation portion 82. That is, the first electrode D11 can abut against the first isolation portion 82, and at least part of the first electrode D11 can transmit power signals via the first isolation portion 82. On this basis, by controlling the shape and size of the isolation structure 80, it is possible to selectively electrically connect part or all of the first electrodes D11 according to actual situations, offering higher flexibility.

In some embodiments, the isolation structure 80 includes a light-shielding material. The first isolation portion 82 may include a light-shielding material, or the second isolation portion 83 may include a light-shielding material. Further in one embodiment, both the first isolation portion 82 and the second isolation portion 83 include a light-shielding material.

In the embodiments of the present application, in addition to enabling the manufacturing of the light-emitting units 21 without the need for a fine metal mask, the isolation structure 80 can also be used to absorb or block some oblique light, reducing the risk of crosstalk between different oblique lights, and improving display accuracy and display effect.

In some embodiments, as shown in FIG. 10, the display panel further includes an encapsulation functional layer 90 disposed on a side of the light-emitting functional layer 20 away from the substrate 10. The orthographic projection of the encapsulation functional layer 90 on the substrate 10 covers the orthographic projections of the plurality of light-emitting units 21 on the substrate 10.

In the embodiments of the present application, the encapsulation functional layer 90 is a film layer structure in the display panel that provides encapsulation and protection. The encapsulation functional layer 90 is located on a side of the light-emitting units 21 away from the substrate 10, i.e., on the light-emitting surface of the light-emitting units 21. Moreover, the orthographic projection of the encapsulation functional layer 90 on the substrate 10 can simultaneously cover the orthographic projections of the plurality of light-emitting units 21 on the substrate 10. Thus, the encapsulation functional layer 90 can provide encapsulation and protection for the plurality of light-emitting units 21, thereby improving the reliability of the display panel.

The specific film layer composition of the encapsulation functional layer 90 is not limited in the embodiments of the present application. In one embodiment, the encapsulation functional layer 90 includes a first atomic layer 91, an inorganic encapsulation layer 92 located on a side of the first atomic layer 91 away from the substrate 10, and a second atomic layer 93 located on a side of the inorganic encapsulation layer 92 away from the substrate 10.

Regarding the positional relationship between the color conversion layer 40 and the first atomic layer 91, the inorganic encapsulation layer 92, and the second atomic layer 93, the embodiments of the present application impose no limitation. In one embodiment, the color conversion layer 40 is located on a side of the second atomic layer 93 away from the substrate 10, meaning the color conversion layer 40 is located outside the encapsulation functional layer 90.

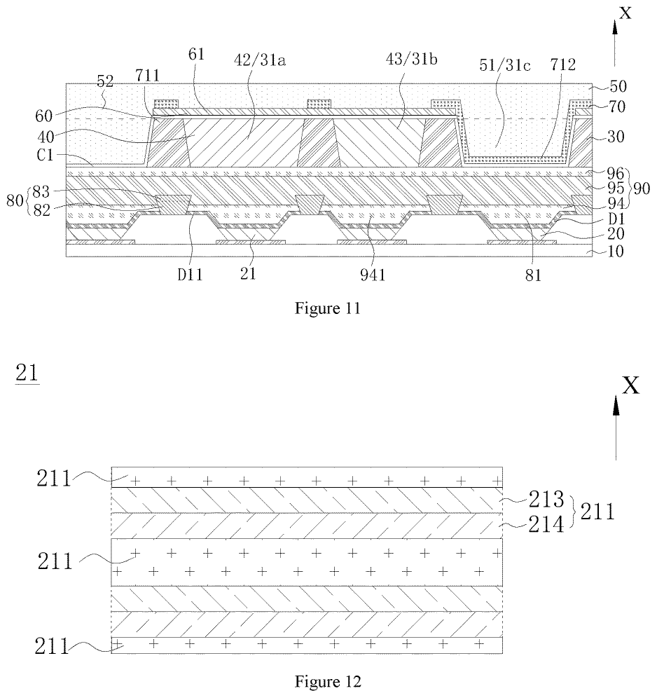

Certainly, in other embodiments, please refer to FIG. 11, the encapsulation functional layer 90 includes a first inorganic layer 94, an organic encapsulation layer 95 located on a side of the first inorganic layer 94 away from the substrate 10, and a second inorganic layer 96 located on a side of the organic encapsulation layer 95 away from the substrate 10. Here, the first inorganic layer 95, the organic encapsulation layer 95, and the second inorganic layer 96 together constitute a thin-film encapsulation structure, thereby improving the encapsulation protection effect for the plurality of light-emitting units 21.

Regarding the positional relationship between the color conversion layer 40 and the first inorganic layer 94, the organic encapsulation layer 95, and the second inorganic layer 96, the embodiments of the present application impose no limitation. In one embodiment, the color conversion layer 40 is located between the organic encapsulation layer 95 and the second inorganic layer 96, meaning the color conversion layer 40 is located inside the encapsulation functional layer 90.

In the embodiments of the present application, by arranging the color conversion layer 40 between the organic encapsulation layer 95 and the second inorganic layer 96, the color conversion layer 40 can be positioned closer to the light-emitting units 21 in the thickness direction X of the display panel. This allows more light emitted by the light-emitting units 21 to enter the color conversion layer 40, thereby helping to improve the excitation brightness of the color conversion units 41 and enhance the visual experience of the display panel.

Certainly, in other embodiments, the color conversion layer 40 is located on a side of the second inorganic layer 96 away from the substrate 10, meaning the color conversion layer 40 is located on a side of the encapsulation functional layer 90 away from the substrate 10. In this way, the color conversion layer 40 is formed after the encapsulation functional layer 90, and its presence does not affect the preparation of the encapsulation functional layer 90, thereby improving the encapsulation reliability of the encapsulation functional layer 90.

In some embodiments, the display panel further includes an isolation structure 80 disposed on a side of the substrate 10. The isolation structure 80 encloses to form a plurality of isolation openings 81, and the plurality of light-emitting units 21 correspond to the plurality of isolation openings 81. Here, the first inorganic layer 94 includes a plurality of encapsulation portions 941 respectively located within the plurality of isolation openings 81.

Due to the presence of the isolation structure 80, the prepared first inorganic layer 94 can include a plurality of encapsulation portions 941 corresponding to the light-emitting units 21 and located within the isolation openings 81. This helps improve the encapsulation effect of the first inorganic layer 91 on each light-emitting unit 21. The portions of the first inorganic layer 94 located within different isolation openings 81 may be connected to each other or spaced apart from each other, and the embodiments of the present application impose no limitation on this.

In some embodiments, please refer to FIG. 11, the light-emitting unit 21 includes a plurality of stacked light-emitting layers 211.

The light-emitting unit 21 includes a plurality of light-emitting layers 211, and the light emitted by the light-emitting unit 21 is a combination of light emitted by the plurality of light-emitting layers 211, thereby improving the luminous brightness of a single light-emitting unit 21. For a single light-emitting unit 21, the emission colors of different light-emitting layers 211 may be the same or different. The embodiments of the present application impose no limitation on this.

In one embodiment, the light-emitting unit 21 further includes a connection layer 212 disposed between adjacent light-emitting layers 211. The connection layer 212 includes a stacked first doped layer 213 and a second doped layer 214. The first doped layer 213 and the second doped layer 214 are respectively used to transport holes or electrons into two adjacent light-emitting layers 211 to meet the light-emitting requirements of the light-emitting unit 21.

The composition of the light-emitting layers 211 in different light-emitting units 21 may be the same or different. In one embodiment, the color settings of corresponding light-emitting layers 211 in different light-emitting units 21 are consistent. The corresponding light-emitting layers 211 mentioned here refer to:

In different light-emitting units 21, light-emitting layers 211 at the same relative position. For example, they may be the light-emitting layers 211 closest to the corresponding first electrode D11 in different light-emitting units 21, or the light-emitting layers 211 farthest from the corresponding first electrode D11 in different light-emitting units 21. By setting the colors of corresponding light-emitting layers 211 in different light-emitting units 21 consistently, during the preparation process of the light-emitting units 21, the corresponding light-emitting layers 211 of different light-emitting units 21 can be formed together in the same preparation step, eliminating the need for repeated evaporation and etching processes. This improves the luminous brightness while enhancing the preparation efficiency of the display panel.

In some embodiments, within the same light-emitting unit 21, at least some of the light-emitting layers 211 have the same color. For example, the same light-emitting unit 21 may include a plurality of blue light-emitting layers 211 for emitting blue light, which helps improve luminous efficiency and is beneficial for extending the service life of the light-emitting unit 21, making it suitable for long-term use.

Certainly, in other embodiments, within the same light-emitting unit 21, at least some of the light-emitting layers 211 have different colors. For example, the same light-emitting unit 21 may simultaneously include red light-emitting layers 211 and blue light-emitting layers 211, or the same light-emitting unit 21 may simultaneously include green light-emitting layers 211 and blue light-emitting layers 211.

In some embodiments, the color of the light-emitting layer 211 is one of green and blue. For example, the light-emitting unit 21 may include a plurality of stacked blue light-emitting layers 211 and green light-emitting layers 211. The presence of green light-emitting layers 211 helps reduce the power consumption of the display panel. Further in one embodiment, the light-emitting unit 21 may include a plurality of stacked blue light-emitting layers 211; and/or, the light-emitting unit 21 may also include stacked blue light-emitting layers 211 and green light-emitting layers 211.

In a second aspect, as shown in FIG. 10, an embodiment of the present application provides a display panel. The display panel includes a substrate 10, a light-emitting functional layer 20, a bank structure layer 30, a color conversion layer 40, and a first filter layer 60. The light-emitting functional layer 20 is disposed on one side of the substrate 10 and includes a plurality of light-emitting units 21. The bank structure layer 30 is disposed on a side of the light-emitting functional layer 20 away from the substrate 10, and the bank structure layer 30 encloses to form a plurality of first openings 31 respectively corresponding to the plurality of light-emitting units 21. The color conversion layer 40 is disposed on the side of the light-emitting functional layer 20 away from the substrate 10. The color conversion layer 40 includes a plurality of color conversion units 41, which include a first color conversion unit 42 and a second color conversion unit 43 of different colors. The first color conversion unit 42 and the second color conversion unit 43 are filled in different first openings 31. An inorganic layer C1 is disposed on a side of the color conversion layer 40 away from the substrate 10. The first filter layer 60 is disposed on a side of the inorganic layer C1 away from the substrate 10, and the first filter layer 60 includes a first filter portion 61. The first filter portion 61 is a yellow filter portion. Orthographic projections of both the first color conversion unit 42 and the second color conversion unit 43 on the substrate 10 overlap with an orthographic projection of the first filter portion 61 on the substrate 10. The substrate 10 primarily serves a supporting and carrying function, with other film layers sequentially stacked on the substrate 10. The term “stacked” mentioned here refers to the other film layers being arranged sequentially along a thickness direction X of the substrate 10. The substrate 10 may include multiple film layer structures internally, and the specific composition of the film layer structures within the substrate 10 is not limited in the embodiments of the present application. Moreover, the thickness direction X of the other film layers located on one side of the substrate 10 is generally consistent with the thickness direction X of the substrate 10 itself. Therefore, for convenience of description, the thickness direction X of the substrate 10 or the thickness direction X of other film layers mentioned subsequently in the embodiments of the present application are all indicated using the same direction. The light-emitting functional layer 20 is located on the same side of the substrate 10. In a direction parallel to the plane of the substrate 10, the light-emitting functional layer includes a plurality of light-emitting units 21, which are the main devices for achieving light-emitting display. Each light-emitting unit 21 may include a stacked structure including a hole injection layer (HIL), a hole transport layer (HTL), a light-emitting layer 211, an electron injection layer (EIL), and an electron transport layer (ETL). In one embodiment, the display panel may further include a pixel definition layer. The pixel definition layer includes pixel defining portions and pixel openings enclosed by the pixel defining portions. The plurality of light-emitting units 21 are respectively disposed within the plurality of pixel openings. The light-emitting units 21 located in different pixel openings may be spaced apart from each other, or at least some adjacent light-emitting units 21 in adjacent pixel openings may be integrally connected. This is not limited in the embodiments of the present application. Furthermore, the display panel further includes a first electrode layer D1 and a second electrode layer located on both sides of the light-emitting functional layer 20 in the thickness direction X. The first electrode layer D1 is located on a side of the light-emitting functional layer 20 away from the substrate 10, and the second electrode layer is located on a side of the light-emitting functional layer 20 facing the substrate 10. The first electrode layer D1 includes a first electrode D11, and the second electrode layer includes a plurality of second electrodes. The plurality of second electrodes correspond to the light-emitting units 21, and the first electrode D11 and the second electrodes jointly drive and control whether the light-emitting units 21 emit light. For example, the first electrode D11 is a cathode, and the second electrodes are anodes. The color conversion layer 40 is located on a side of the light-emitting functional layer 20 away from the substrate 10. The color conversion layer 40 includes a plurality of color conversion units 41. The color conversion units 41 can change the color of light after being excited by light of a specific color and allow the color-changed light to exit the display panel. In one embodiment, the color conversion units 41 may be quantum dot structures. Further, in the embodiments of the present application, the orthographic projection of the color conversion unit 41 on the substrate 10 at least partially overlaps with the orthographic projection of the light-emitting unit 21 on the substrate 10. That is, the color conversion unit 41 can be arranged corresponding to the light-emitting unit 21, and light of a specific color emitted by the light-emitting unit 21 can irradiate the color conversion unit 41 and excite it, causing the color conversion unit 41 to emit light of a different color from that of the light-emitting unit 21. The bank structure layer 30 can define and form a plurality of first openings 31. The plurality of color conversion units 41 include a first color conversion unit 42 and a second color conversion unit 43 of different colors. The first color conversion unit 42 and the second color conversion unit 43 are located in different first openings 31, respectively. The specific color types of the first color conversion unit 42 and the second color conversion unit 43 are not limited in the embodiments of the present application, as long as the colors of the first color conversion unit 42 and the second color conversion unit 43 are different and both are different from the light-emitting color of the light-emitting unit 21. The first filter layer 60 is disposed on a side of the color conversion layer 40 away from the substrate 10. The first filter layer 60 includes a first filter portion 61. The color conversion unit 41 is arranged corresponding to the first filter portion 61, and their orthographic projections on the substrate 10 at least partially overlap. The first filter portion 61 can filter light exiting from the color conversion unit 41 to improve the accuracy of the final light color exiting the display panel. In the embodiments of the present application, the first filter portion 61 can not only be arranged corresponding to the first color conversion unit 42 to filter light at the first color conversion unit 42, but also be arranged corresponding to the second color conversion unit 43 to filter light at the second color conversion unit 43. In this way, the first filter portions 61 corresponding to color conversion units 41 of different colors can include the same material and be formed together in the same process step, which helps simplify the manufacturing process, improve production efficiency, and reduce manufacturing costs.

In addition, the inorganic layer C1 can separate the color conversion layer 40 from the first filter layer 60, thereby reducing the structural impact of the fabrication process of the first filter layer 60 on the color conversion layer 40. The inorganic layer C1 has a full-surface structure, and the orthographic projection of the inorganic layer C1 on the substrate 10 overlaps with the orthographic projections of both the first color conversion unit 42 and the second color conversion unit 43 on the substrate 10.

In some embodiments, the first filter portion 61 corresponding to the first color conversion unit 42 and the first filter portion 61 corresponding to the second color conversion unit 43 are integrally connected.

In the embodiments of the present application, the orthographic projection of a single first filter portion 61 on the substrate 10 overlaps with both the orthographic projection of the first color conversion unit 42 on the substrate 10 and the orthographic projection of the second color conversion unit 43 on the substrate 10. This helps to increase the orthographic projection area of the single first filter portion 61 on the substrate 10, thereby reducing the fabrication difficulty of the first filter portion 61. Simultaneously, it helps to lower the alignment accuracy requirement of the first filter portion 61 relative to the first color conversion unit 42 and the second color conversion unit 43, reduces the process complexity of the display panel, and improves the fabrication yield.

It should be noted that, depending on actual needs, the first filter portion 61 corresponding to a single first color conversion unit 42 and the first filter portion 61 corresponding to a single second color conversion unit 43 may be integrally connected. In one embodiment, the first filter portions 61 corresponding to multiple first color conversion units 42 and the first filter portions 61 corresponding to multiple second color conversion units 43 may be integrally connected. The embodiments of the present application impose no limitation in this regard.

In some embodiments, the first color conversion unit 42 is a red conversion unit 41, the second color conversion unit 43 is a green conversion unit 41, and the first filter portion 61 includes a yellow filter portion.

In the embodiments of the present application, the first filter portion 61 is a yellow filter portion. The yellow filter portion allows yellow light to pass through and absorbs light of other colors. In the optical color model, yellow light is formed by combining red light and green light. Therefore, the yellow filter portion allows both red light and green light to exit. In other words, the first filter portion 61 can be arranged corresponding to both the first color conversion unit 42 and the second color conversion unit 43, which helps to simplify the process steps, improve fabrication efficiency, and reduce fabrication costs.

In some embodiments, the orthographic projections of the multiple first color conversion units 42 and the multiple second color conversion units 43 on the substrate 10 all overlap with the orthographic projection of the same first filter portion 61 on the substrate 10. This can further increase the orthographic projection area of the single first filter portion 61 on the substrate 10, reduce the alignment accuracy requirement of the first filter portion 61 relative to the first color conversion unit 42 and the second color conversion unit 43, and improve the fabrication yield.

In some embodiments, the orthographic projection of a single first filter portion 61 on the substrate 10 covers the orthographic projections of all the first color conversion units 42 and all the second color conversion units 43 on the substrate 10.

In the embodiments of the present application, by configuring the first filter portion 61 as a full-surface structure, the fabrication difficulty of the first filter portion 61 is further reduced. Simultaneously, the alignment accuracy requirement of the first filter portion 61 relative to the first color conversion unit 42 and the second color conversion unit 43 is further lowered, thereby improving the fabrication yield.

In some embodiments, the display panel further includes a transparent functional layer 50 disposed on a side of the first filter layer 60 away from the substrate 10. The transparent functional layer 50 includes a filling portion 51 and a covering portion 52 located on a side of the filling portion 51 away from the substrate 10. The multiple first openings 31 include a first-type opening 31a, a second-type opening 31b, and a third-type opening 31c. The first color conversion unit 42 is filled in the first-type opening 31a, the second color conversion unit 43 is filled in the second-type opening 31b, and the filling portion 51 is filled in the third-type opening 31c.

The transparent functional layer 50 is disposed on a side of the color conversion layer 40 away from the substrate 10, meaning the transparent functional layer 50 is formed after the color conversion layer 40. The transparent functional layer 50 includes the covering portion 52 and the filling portion 51. Both the covering portion 52 and the filling portion 51 include transparent materials. Light reaching the transparent functional layer 50 can exit the display panel through at least one of the covering portion 52 and the filling portion 51. The covering portion 52 and the color conversion layer 40 are stacked in the thickness direction X of the display panel, and the orthographic projection of the covering portion 52 on the substrate 10 can cover the orthographic projections of the multiple color conversion units 41 on the substrate 10. The filling portion 51 and the color conversion units 41 are arranged spaced apart in a direction parallel to the plane of the substrate 10. A portion of the structure in the bank structure layer 30 is provided between the filling portion 51 and the color conversion units 41, while the covering portion 52 and the color conversion units 41 may be in direct contact, or other film layer structures may exist between them.

The multiple first openings 31 in the bank structure layer 30 include the first-type opening 31a, the second-type opening 31b, and the third-type opening 31c. There are multiple first-type openings 31a, second-type openings 31b, and third-type openings 31c, and their interiors are filled with different structures, respectively. In one embodiment, the first color conversion unit 42, the second color conversion unit 43, and the filling portion 51 are filled in the first-type opening 31a, the second-type opening 31b, and the third-type opening 31c, respectively. Based on this, the color of light emitted from the region where the first-type opening 31a is located corresponds to the color of the first color conversion unit 42, the color of light emitted from the region where the second-type opening 31b is located corresponds to the color of the second color conversion unit 43, and the color of light emitted from the region where the third-type opening 31c is located corresponds to the inherent light-emitting color of the light-emitting unit 21.

Taking a quantum dot display device as an example, in related technologies, a quantum dot structure is provided on the light-emitting side of some light-emitting structures, while a transparent structure is provided on the light-emitting side of other light-emitting structures. The quantum dot structure and the transparent structure are arranged side by side in the horizontal direction, and a transparent film layer is further coated on the light-emitting side of the quantum dot structure and the transparent structure to provide protection and other effects. Such a design often involves multiple process steps during fabrication, making the process relatively complex and affecting fabrication efficiency and cost.

However, in the embodiments of the present application, the transparent portion filled in the third type of opening 31c and the covering portion 52 used to cover the transparent portion and the color conversion unit 41 are both located within the transparent functional layer 50, and the two are integrally connected. In other words, they include the same material and are formed together in the same process step. Compared to conventional processes where the transparent film layer and the transparent structure are formed separately, and the transparent structure requires the use of a mask, this design can save one process step. Moreover, since the formed transparent functional layer 50 itself is a full-surface structure, this design can also save two mask processes, simplifying the preparation difficulty, reducing preparation costs, and improving preparation efficiency.

In some embodiments, the first filter portion 61 corresponding to the first color conversion unit 42 and the first filter portion 61 corresponding to the second color conversion unit 43 are spaced apart. That is, the first color conversion unit 42 and the second color conversion unit 43 are respectively arranged corresponding to different first filter portions 61. Further in one embodiment, adjacent first filter portions 61 are spaced apart to form a gap space J, and a portion of the structure of the covering portion 52 is located within the gap space J.

In the embodiments of the present application, in addition to covering the surface of the first filter portion 61 facing away from the substrate 10, the covering portion 52 can also be attached to the peripheral side surface of the first filter portion 61. This can further improve the covering effect of the covering portion 52 on the first filter portion 61, enhance the protective effect of the transparent functional layer 50 on the first filter layer 60, and improve the use reliability and service life of the display panel.

In some embodiments, the display panel further includes a second filter layer 70 disposed on a side of the first filter layer 60 facing away from the substrate 10. The second filter layer 70 includes a fourth filter portion 71, and the fourth filter portion 71 has the same color as the light-emitting unit 21. The fourth filter portion 71 includes a first part 711 located on a side of the first filter layer 60 facing away from the substrate 10. An orthographic projection of the first part 711 on the substrate 10 is located between orthographic projections of adjacent light-emitting units 21 on the substrate 10.

Similar to the first filter layer 60, the second filter layer 70 is also a film layer structure used for filtering light, and the second filter layer 70 is formed after the first filter layer 60. The second filter layer 70 includes a fourth filter portion 71, and the fourth filter portion 71 has the same color as the light-emitting unit 21, meaning the fourth filter portion 71 has a different color from the first filter portion 61. In one embodiment, the light-emitting unit 21 is a blue light-emitting unit 21, and the fourth filter portion 71 is a blue filter portion.

The first part 711 is the structure within the fourth filter portion 71 correspondingly located between adjacent light-emitting units 21, and the first part 711 is located on the light-emitting side of the color conversion unit 41 and the filling portion 51. The projection positional relationship of the first part 711 relative to the color conversion unit 41 and the filling portion 51 is not limited in the embodiments of the present application. In one embodiment, at least a portion of the orthographic projection of the first part 711 on the substrate 10 is located between orthographic projections of two adjacent color conversion units 41 on the substrate 10. In this way, oblique light emitted from the color conversion unit 41 will propagate to the first part 711. Since the first part 711 and the color conversion unit 41 have different colors, the oblique light emitted from the color conversion unit 41 will be absorbed by the first part 711, thereby reducing the risk of crosstalk between light of different colors.

Certainly, in other optional embodiments, at least a portion of the orthographic projection of the first part 711 on the substrate 10 is located between orthographic projections of an adjacent color conversion unit 41 and the filling portion 51 on the substrate 10. Under this design, oblique light emitted from the color conversion unit 41 will also be absorbed by the first part 711, thereby reducing the risk of light crosstalk.

In some embodiments, the fourth filter portion 71 further includes a second part 712. The plurality of first openings 31 include a first type of opening 31a, a second type of opening 31b, and a third type of opening 31c. The first color conversion unit 42 is filled in the first type of opening 31a, the second color conversion unit 43 is filled in the second type of opening 31b, and the second part 712 is located within the third type of opening 31c.

In addition to the first part 711, the fourth filter portion 71 further includes a second part 712. The second part 712 is not located between adjacent light-emitting units 21 but is located within the third type of opening 31c and overlaps with the orthographic projection of the light-emitting unit 21 on the substrate 10. The first part 711 and the second part 712 include the same material and are formed together in the same process step. In one embodiment, the first part 711 and the second part 712 are integrally connected.

Based on the foregoing content, the fourth filter portion 71 has the same color as the light-emitting unit 21, so light emitted by the light-emitting unit 21 can exit through the fourth filter portion 71. In view of this, the embodiments of the present application arrange the second part 712 of the fourth filter portion 71 within the third type of opening 31c, and light emitted by the light-emitting unit 21 can exit the display panel through the third type of opening 31c. Meanwhile, light of other colors reaching the third type of opening 31c will be absorbed by the second part 712, thereby improving the display accuracy and display effect of the display panel.

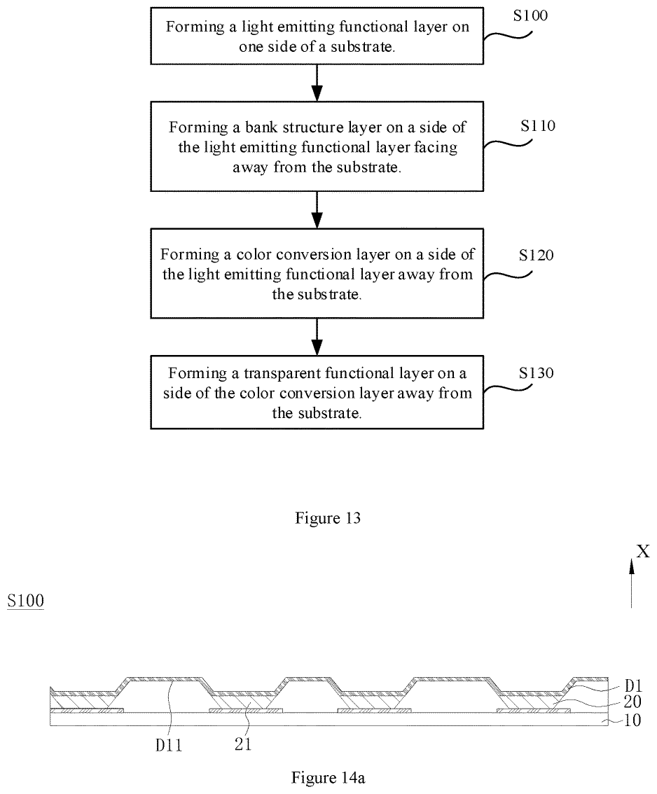

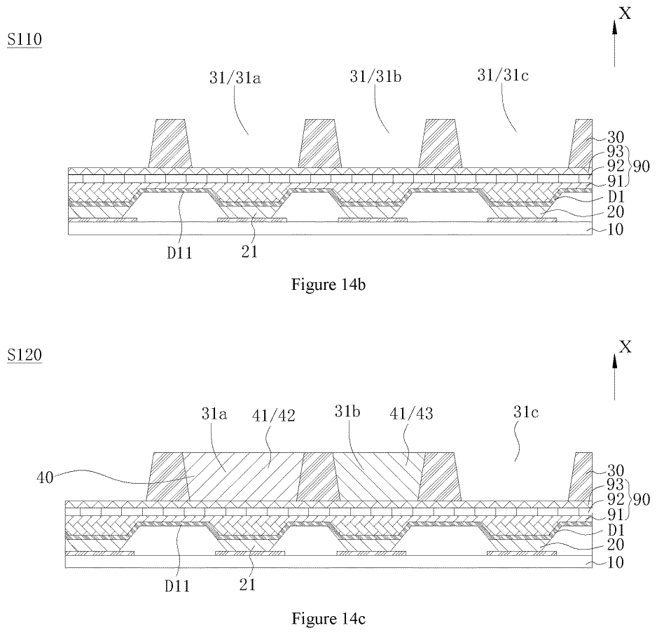

Third Aspect, please refer to FIG. 13 and FIG. 14. The embodiments of the present application provide a method for preparing a display panel. The preparation method includes:

S100: Forming a light-emitting functional layer on one side of a substrate.

Please refer to FIG. 14a. In step S100, the light-emitting functional layer 20 is located on one side of the substrate 10. In a direction parallel to the plane where the substrate 10 is located, the light-emitting functional layer 20 includes a plurality of light-emitting units 21. The light-emitting units 21 are the main devices for achieving light-emitting display. Each light-emitting unit 21 may include a hole injection layer (HIL), a hole transport layer (HTL), a light-emitting layer 211, an electron injection layer (EIL), and an electron transport layer (ETL) stacked in sequence.

S110: Forming a bank structure layer on a side of the light-emitting functional layer facing away from the substrate.

Please refer to FIG. 14b. In step S110, the bank structure layer 30 encloses to form a plurality of first openings 31 respectively corresponding to a plurality of light-emitting units 21. The plurality of first openings 31 include a first type of opening 31a, a second type of opening 31b, and a third type of opening 31c. The orthographic projection of the first opening 31 on the substrate 10 overlaps with the orthographic projection of the light-emitting unit 21 on the substrate 10. Different first openings 31 are respectively arranged corresponding to different light-emitting units 21. The first opening 31 is used to limit and accommodate part of the film layer structure to meet the preparation requirements of the display panel. Regarding the specific material composition of the bank structure layer 30, the embodiments of the present application impose no limitation. In one embodiment, the bank structure layer 30 may include a light-shielding material, and the bank structure layer 30 can also be used to block or absorb part of the oblique light, thereby reducing the risk of display crosstalk.

S120: Forming a color conversion layer on a side of the light-emitting functional layer away from the substrate.

Please refer to FIG. 14c. In step S120, the color conversion layer 40 includes a plurality of color conversion units 41. The color conversion layer 40 is located on a side of the light-emitting functional layer 20 away from the substrate 10. The color conversion layer 40 includes a plurality of color conversion units 41. The color conversion unit 41 can change the color of light after being excited by light of a specific color and allow the light with the changed color to exit the display panel.

The plurality of color conversion units 41 include a first color conversion unit 42 and a second color conversion unit 43 of different colors. The first color conversion unit 42 is filled in the first type of opening 31a, and the second color conversion unit 43 is filled in the second type of opening 31b. Regarding the specific color types of the first color conversion unit 42 and the second color conversion unit 43, the embodiments of the present application impose no limitation, as long as the colors of the first color conversion unit 42 and the second color conversion unit 43 are different and both are different from the light-emitting color of the light-emitting unit 21.

S130: Forming a transparent functional layer on a side of the color conversion layer away from the substrate.

Please refer to FIG. 14d. In step S130, the transparent functional layer 50 includes a filling portion 51 and a covering portion 52 located on a side of the filling portion 51 away from the substrate 10. The filling portion 51 is filled in the third type of opening 31c. The covering portion 52 covers the filling portion 51 and covers at least part of the first color conversion unit 42 and the second color conversion unit 43, and is integrally connected with the filling portion 51.

In the embodiments of the present application, the filling portion 51 and the covering portion 52 are an integrally connected structure, both including the same material and formed together in the same process step. Compared to conventional processes where the transparent film layer and the transparent structure are formed separately, and the transparent structure requires a mask, this design can save process steps. Moreover, since the formed transparent functional layer 50 itself is a full-surface structure, this design can also save two mask processes, simplifying the preparation difficulty, reducing preparation costs, and improving preparation efficiency.

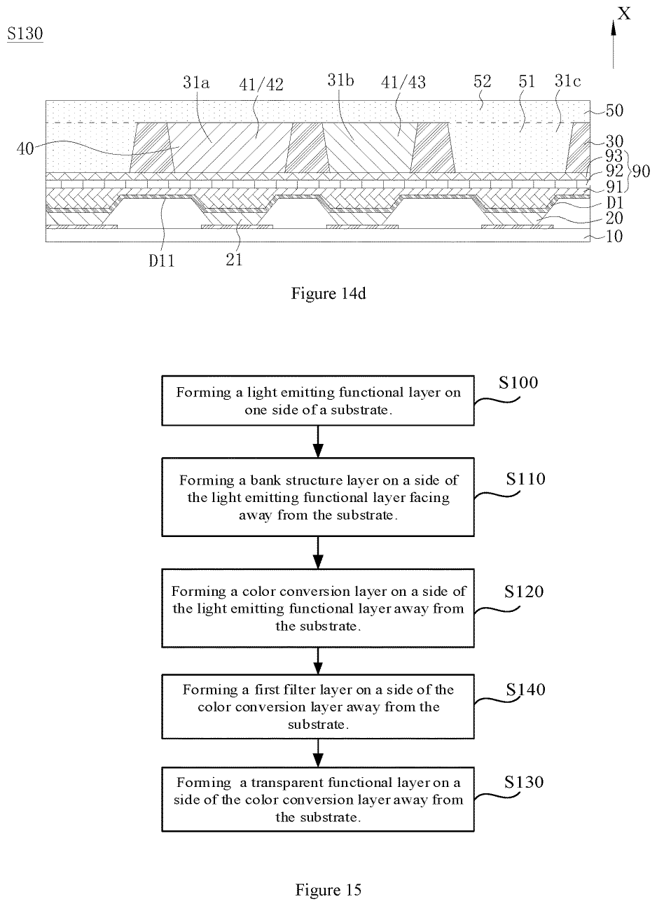

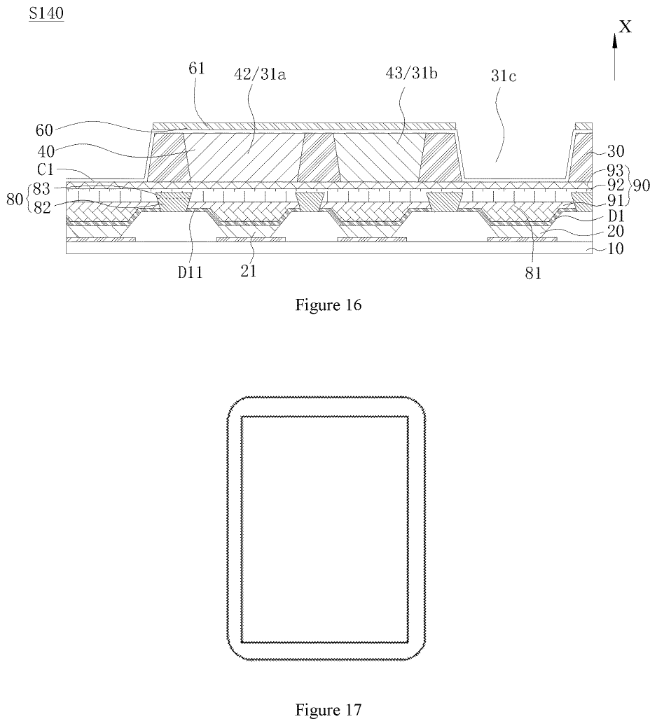

In some embodiments, please refer to FIG. 15 and FIG. 16. Before step S130, the method further includes:

S140: Forming a first filter layer on a side of the color conversion layer away from the substrate.

Please refer to FIG. 16. In step S140, the first filter layer 60 includes a first filter portion 61. The orthographic projections of both the first color conversion unit 42 and the second color conversion unit 43 on the substrate 10 overlap with the orthographic projection of the first filter portion 61 on the substrate 10. The first filter portion 61 can filter the light exiting from the color conversion unit 41 to improve the accuracy of the color of the light finally exiting the display panel.

In the embodiments of the present application, the first filter portion 61 can not only be arranged corresponding to the first color conversion unit 42 to filter the light at the first color conversion unit 42, but can also be arranged corresponding to the second color conversion unit 43 to filter the light at the second color conversion unit 43. In this way, the first filter portions 61 corresponding to color conversion units 41 of different colors can include the same material and be formed together in the same process step, which helps simplify the process flow, improve preparation efficiency, and reduce preparation costs.

In some embodiments, the first color conversion unit 42 is a red conversion unit 41, the second color conversion unit 43 is a green conversion unit 41, and the first filter portion 61 includes a yellow filter portion.

In the embodiments of the present application, the first filter portion 61 is a yellow filter portion. The yellow filter portion allows yellow light to pass through and absorbs light of other colors. In the optical color model, yellow light is formed by combining red light and green light. Therefore, the yellow filter portion allows both red light and green light to exit. In other words, the first filter portion 61 can be arranged corresponding to both the first color conversion unit 42 and the second color conversion unit 43. Thus, both the first color conversion unit 42 and the second color conversion unit 43 can be arranged to overlap with the first filter portion 61, thereby simplifying the process flow of the first filter layer 60, improving preparation efficiency, and reducing preparation costs.

In some embodiments, the first filter portion 61 includes a first colloid portion and a first quantum dot structure located within the first colloid portion.

The first filter portion 61 includes both quantum dot material and colloid material, meaning the first filter portion 61 is a quantum dot photoresist. Quantum dot photoresist is a new type of photolithographic material that mixes quantum dot light-emitting material with photoresist and uses suitable semiconductor processes and photolithography techniques to pattern it on the substrate 10. For example, the patterning method for quantum dot photoresist can be consistent with that of photoresist. In one embodiment, in step S140, the first filter portion 61 is formed through a development and exposure process.

In the embodiments of the present application, the structural composition of the first filter portion 61 is adjusted. The first filter portion 61 is not a conventional filter structure but is a quantum dot photoresist including a first colloid portion and a first quantum dot structure located within the first colloid portion. This design, on one hand, meets the filtering needs, and on the other hand, allows the first filter portion 61 to be patterned through a development and exposure process. Compared to conventional etching processes, this design helps simplify the patterning process of the first filter portion 61.

In a fourth aspect, referring to FIG. 17, an embodiment of the present application provides a display device. The display device includes the display panel according to any one of the foregoing embodiments or a display panel formed by the preparation method according to any one of the foregoing embodiments. It should be noted that the display device provided in the embodiment of the present application has the beneficial effects of the display panel and the preparation method of the display panel according to any one of the foregoing embodiments. For details, please refer to the foregoing description of the beneficial effects of the display panel and the preparation method of the display panel, which will not be repeated in the embodiment of the present application. Although the embodiments disclosed in the present application are as described above, the content is only for facilitating the understanding of the present application and is not intended to limit the present disclosure. Any modifications and changes can be made in form and details without departing from the spirit and scope disclosed in the present application. However, the protection scope of the present application shall still be subject to the scope defined by the appended claims. The above are only specific embodiments of the present application. Those skilled in the art can clearly understand that, for the convenience and conciseness of description, replacements of other connection methods described above can refer to the corresponding processes in the foregoing method embodiments, which will not be repeated here. It should be understood that the protection scope of the present application is not limited thereto. Any person skilled in the art can easily think of various equivalent modifications or replacements within the technical scope disclosed in the present application, and these modifications or replacements shall fall within the protection scope of the present application.

What is claimed is:

1. A display panel, comprising:
a substrate;
a light-emitting functional layer disposed on a side of the substrate, the light-emitting functional layer comprising a plurality of light-emitting units;
a bank structure layer disposed on a side of the light-emitting functional layer away from the substrate, the bank structure layer enclosing to form a plurality of first openings respectively corresponding to the plurality of light-emitting units, the plurality of first openings comprising at least one first-type opening, at least one second-type opening, and at least one third-type opening;
a color conversion layer disposed on a side of the light-emitting functional layer away from the substrate, the color conversion layer comprising a plurality of color conversion units, the plurality of color conversion units comprising at least one first color conversion unit and at least one second color conversion unit having different colors, the first color conversion unit filling the first-type opening, and the second color conversion unit filling the second-type opening; and
a transparent functional layer disposed on a side of the color conversion layer away from the substrate, the transparent functional layer comprising at least one filling portion and at least one covering portion located on a side of the filling portion away from the substrate, the filling portion filling the third-type opening, the covering portion covering the filling portion and covering at least a part of the first color conversion unit and at least a part of the second color conversion unit, and the covering portion being integrally connected with the filling portion.

2. The display panel according to claim 1, further comprising a first filter layer disposed between the color conversion layer and the transparent functional layer, an orthographic projection of the color conversion unit on the substrate overlapping with an orthographic projection of the first filter layer on the substrate, the first filter layer comprising at least one first filter portion;
wherein the covering portion is disposed covering the first filter layer;
the covering portion is disposed covering the first color conversion unit, the second color conversion unit, and the filling portion.

3. The display panel according to claim 2, wherein the first color conversion unit is a red conversion unit, the second color conversion unit is a green conversion unit, the first filter portion is a yellow filter portion which allows yellow light to pass through while absorbing light of other colors, orthographic projections of the first color conversion unit and the second color conversion unit on the substrate both overlap with an orthographic projection of the first filter portion on the substrate;
the first filter portion corresponding to the first color conversion unit and the first filter portion corresponding to the second color conversion unit are spaced apart;
adjacent first filter portions are spaced apart to form a gap space, and a part of the structure of the covering portion is located within the gap space.

4. The display panel according to claim 2, wherein the display panel further comprises an inorganic layer disposed between the color conversion layer and the first filter layer, the filling portion and the first filter portion are both located on a side of the inorganic layer away from the substrate.

5. The display panel according to claim 2, wherein the first filter layer comprises at least one second filter portion and at least one third filter portion having different colors, an orthographic projection of the second filter portion on the substrate overlaps with an orthographic projection of the first color conversion unit on the substrate, an orthographic projection of the third filter portion on the substrate overlaps with an orthographic projection of the second color conversion unit on the substrate;
adjacent second filter portion and third filter portion are spaced apart; or,
adjacent second filter portion and third filter portion overlap to form an overlapping portion, an orthographic projection of the overlapping portion on the substrate is located between orthographic projections of the adjacent first color conversion unit and the second color conversion unit on the substrate.

6. The display panel according to claim 2, wherein orthographic projections of the first color conversion unit and the second color conversion unit on the substrate both overlap with an orthographic projection of the first filter portion on the substrate;
wherein the first filter portion corresponding to the first color conversion unit and the first filter portion corresponding to the second color conversion unit are integrally formed;
orthographic projections of the plurality of first color conversion units and the plurality of second color conversion units on the substrate all overlap with an orthographic projection of the same first filter portion on the substrate;
an orthographic projection of a single first filter portion on the substrate covers orthographic projections of all the first color conversion units and all the second color conversion units on the substrate, and the first filter portion encloses to form a plurality of second openings, orthographic projections of the plurality of second openings and orthographic projections of the plurality of third-type openings are correspondingly overlapped;
wherein a part of the structure of the covering portion is located within the second openings.

7. The display panel according to claim 2, wherein the first filter portion comprises a first colloid portion and a first quantum dot structure located within the first colloid portion;
a material of the first colloid portion comprises a photosensitive material;
the display panel further comprises a protective layer disposed between the first filter layer and the transparent functional layer, the protective layer covering the first filter portion;
at least a part of the color conversion units comprises a second colloid portion and a second quantum dot structure located within the second colloid portion.

8. The display panel according to claim 2, further comprising a second filter layer disposed on a side of the first filter layer away from the substrate, the second filter layer comprising at least one fourth filter portion, the fourth filter portion having the same color as the light-emitting unit;
wherein the fourth filter portion comprises a first part located on a side of the covering portion facing the substrate, an orthographic projection of the first part on the substrate is located between orthographic projections of adjacent light-emitting units on the substrate.

9. The display panel according to claim 8, wherein an orthographic projection of at least a part of the first part on the substrate is located between orthographic projections of two adjacent color conversion units on the substrate; or,
an orthographic projection of at least a part of the first part on the substrate is located between orthographic projections of an adjacent color conversion unit and the filling portion on the substrate.

10. The display panel according to claim 2, wherein the first filter layer comprises at least one first filter portion, orthographic projections of the first color conversion unit and the second color conversion unit on the substrate both overlap with an orthographic projection of the first filter portion on the substrate;
the number of the first filter portions is plural, adjacent first filter portions are spaced apart to form a gap space, and the first portion is located within the gap space; or,
the first filter portions corresponding to the color conversion units of different colors are integrally connected, and the first portion is disposed in contact with a surface of the first filter portion facing away from the substrate.

11. The display panel according to claim 8, wherein the fourth filter portion further comprises a second portion, the second portion is located within the third type opening and is disposed to overlap with an orthographic projection of the light-emitting unit on the substrate;
the first portion and the second portion are integrally connected;
the second portion is located on a side of the filling portion facing the substrate;
the first filter layer comprises a first filter portion, orthographic projections of the first color conversion unit and the second color conversion unit on the substrate both overlap with an orthographic projection of the first filter portion on the substrate;
the display panel further comprises an inorganic layer disposed between the color conversion layer and the first filter layer, and the first filter portion and the fourth filter portion are both located on a side of the inorganic layer facing away from the substrate;
the first filter portion and the fourth filter portion are both disposed in contact with the inorganic layer.

12. The display panel according to claim 1, further comprising an isolation structure disposed on one side of the substrate, the isolation structure enclosing to form a plurality of isolation openings, and the plurality of light-emitting units are correspondingly disposed with the plurality of isolation openings;
the isolation structure comprises a first isolation portion and a second isolation portion located on a side of the first isolation portion facing away from the substrate, an orthographic projection of the first isolation portion on the substrate is located within an orthographic projection of the second isolation portion on the substrate;
the display panel further comprises a first electrode layer disposed on a side of the light-emitting functional layer facing away from the substrate, the first electrode layer comprises a plurality of first electrodes correspondingly disposed with the plurality of isolation openings;
the first isolation portion comprises a conductive material, and the first electrode is electrically connected to the first isolation portion.

13. The display panel according to claim 1, further comprising an encapsulation functional layer disposed on a side of the light-emitting functional layer facing away from the substrate, an orthographic projection of the encapsulation functional layer on the substrate covers orthographic projections of the plurality of light-emitting units on the substrate;
the encapsulation functional layer comprises a first atomic layer, an inorganic encapsulation layer located on a side of the first atomic layer facing away from the substrate, and a second atomic layer located on a side of the inorganic encapsulation layer facing away from the substrate;
the color conversion layer is located on a side of the second atomic layer facing away from the substrate;
the encapsulation functional layer comprises a first inorganic layer, an organic encapsulation layer located on a side of the first inorganic layer facing away from the substrate, and a second inorganic layer located on a side of the organic encapsulation layer facing away from the substrate;
the color conversion layer is located between the organic encapsulation layer and the second inorganic layer;
the color conversion layer is located on a side of the second inorganic layer facing away from the substrate;
the display panel further comprises an isolation structure disposed on one side of the substrate, the isolation structure enclosing to form a plurality of isolation openings, and the plurality of light-emitting units are correspondingly disposed with the plurality of isolation openings;
wherein, the first inorganic layer comprises a plurality of encapsulation portions respectively disposed within the plurality of isolation openings.

14. The display panel according to claim 1, wherein one of the light-emitting units comprises a plurality of light-emitting layers stacked;
in the same light-emitting unit, colors of at least part of the light-emitting layers are the same; or, in the same light-emitting unit, colors of at least part of the light-emitting layers are different;
the light-emitting unit further comprises a connection layer disposed between adjacent light-emitting layers, the connection layer comprises a first doped layer and a second doped layer stacked, and the first doped layer and the second doped layer are respectively configured to transport holes or electrons into two adjacent light-emitting layers.

15. A display panel, comprising:
a substrate;
a light-emitting functional layer disposed on one side of the substrate, the light-emitting functional layer comprising a plurality of light-emitting units;
a bank structure layer disposed on a side of the light-emitting functional layer facing away from the substrate, the bank structure layer enclosing to form a plurality of first openings respectively corresponding to the plurality of light-emitting units;
a color conversion layer disposed on a side of the light-emitting functional layer facing away from the substrate, the color conversion layer comprising a plurality of color conversion units, the plurality of color conversion units comprising at least one first color conversion unit and at least one second color conversion unit of different colors, the first color conversion unit is a red conversion unit, the second color conversion unit is a green conversion unit, and the first color conversion unit and the second color conversion unit are filled in different first openings;
an inorganic layer disposed on a side of the color conversion layer facing away from the substrate;
a first filter layer disposed on a side of the inorganic layer facing away from the substrate, the first filter layer comprising a first filter portion;
wherein, the first filter portion is a yellow filter portion which allows yellow light to pass through while absorbing light of other colors, and orthographic projections of the first color conversion unit and the second color conversion unit on the substrate both overlap with an orthographic projection of the first filter portion on the substrate.

16. The display panel according to claim 15, wherein the first filter portion corresponding to the first color conversion unit and the first filter portion corresponding to the second color conversion unit are integrally connected;
orthographic projections of the plurality of first color conversion units and the plurality of second color conversion units on the substrate all overlap with an orthographic projection of the same first filter portion on the substrate;
an orthographic projection of a single first filter portion on the substrate covers orthographic projections of all the first color conversion units and the plurality of second color conversion units on the substrate.

17. The display panel according to claim 15, characterized in that it further comprises a transparent functional layer disposed on a side of the first filter layer away from the substrate, the transparent functional layer comprising a filling portion and a covering portion located on a side of the filling portion away from the substrate; the plurality of first openings comprise at least one first-type opening, at least one second-type opening, and at least one third-type opening, the first color conversion unit fills the first-type opening, the second color conversion unit fills the second-type opening, and the filling portion fills the third-type opening; the first filter portion corresponding to the first color conversion unit and the first filter portion corresponding to the second color conversion unit are spaced apart; adjacent first filter portions are spaced apart to form a gap space, and a part of the structure of the covering portion is located within the gap space.

18. The display panel according to claim 15, characterized in that it further comprises a second filter layer disposed on a side of the first filter layer away from the substrate, the second filter layer comprising at least one fourth filter portion, the fourth filter portion having the same color as the light-emitting unit; wherein the fourth filter portion comprises a first part located on a side of the first filter layer away from the substrate, and an orthographic projection of the first part on the substrate is located between orthographic projections of adjacent light-emitting units on the substrate.

19. The display panel according to claim 18, characterized in that the fourth filter portion further comprises a second part, the plurality of first openings comprise first-type openings, second-type openings, and third-type openings, the first color conversion unit fills the first-type openings, the second color conversion unit fills the second-type openings, and the second part is located within the third-type openings; the first part and the second part are integrally connected.

20. A display device, characterized in that it comprises the display panel according to claims 1.
